(19) United States
(12) Patent Application Publication
(10) Pub. No.: US 2014/0333451 A1
(43) Pub. Date: Nov. 13, 2014

(54) SYSTEM AND METHOD FOR MONITORING POWER CONSUMPTION OF ELECTRONIC DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: LIANG CHEN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/093,528

(22) Filed: Dec. 2, 2013

(30) Foreign Application Priority Data
May 9, 2013 (CN) 2013101678347

(51) Int. Cl. G01R 19/252; G08B 21/18

(52) U.S. Cl. CPC G01R 19/252; G08B 21/18
USPC 340/815.65; 324/76.11

(57) ABSTRACT

A system for monitoring power consumption of an electronic device, includes a MCU, a processor, and an indicating unit. The MCU includes an inter-integrated circuit and an analog to digital converter. The inter-integrated circuit records a digital output current value and voltage value of each digital electronic component of the electronic device. The analog to digital converter tests an analog output current value and voltage value of each analog electronic component of the electronic device. The analog output current value and voltage value are converted into digital information. The processor processes the digital output current value and voltage value and the digital information to generate a monitoring result.

### BACKGROUND

1. Technical Field

The disclosure generally relates to monitoring systems and methods, and more particularly to a system and method for monitoring power consumption of an electronic device.

2. Description of Related Art

Mobile electronic devices, such as mobile phones and panel computers, are equipped with a battery to provide power. The capacity of the battery limits operation time of the electronic device. Power consumption of each electronic component of the electronic device must be monitored to optimize the power consumption of the battery.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of one embodiment of a system for monitoring power consumption of an electronic device.

FIG. 2 is a flow chart showing one embodiment of a method for monitoring power consumption of an electronic device.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

In general, the word “module,” as used herein, refers to logic embodied in hardware or firmware, or to a collection of software instructions, written in a programming language such as Java, C, or assembly. One or more software instructions in the modules may be embedded in firmware, such as in an erasable-programmable read-only memory (EPROM). The modules described herein may be implemented as either software and/or hardware modules and may be stored in any type of non-transitory computer-readable medium or other storage device. Some non-limiting examples of non-transitory computer-readable media are compact discs (CDs), digital versatile discs (DVDs), Blu-Ray discs, Flash memory, and hard disk drives.

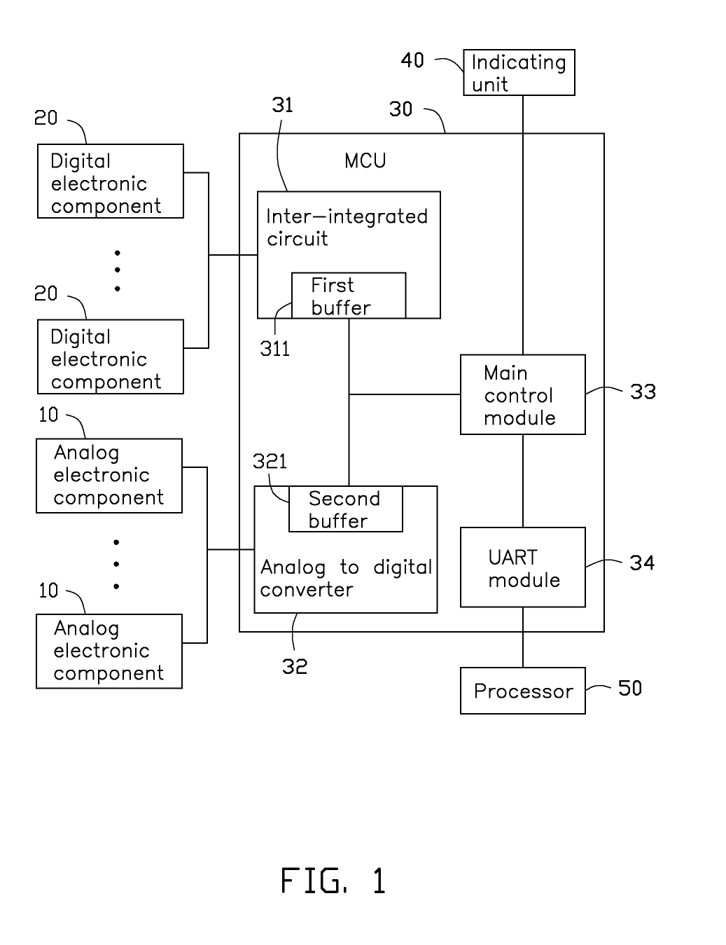

FIG. 1 shows one embodiment of a system for monitoring power consumption of an electronic device. The electronic device includes a plurality of power consumption components, which includes a plurality of analog electronic components 10 and a plurality of digital electronic components 20.

The system for monitoring power consumption of the electronic device includes a micro control unit (MCU) 30, an indicating unit 40, and a processor 50. The MCU 30 includes an inter-integrated circuit 31, an analog to digital converter 32, a main control module 33, and an Universal Asynchronous Receiver/Transmitter (UART) module 34.

The inter-integrated circuit 31 is connected to the plurality of digital electronic components 20. The inter-integrated circuit 31 reads out a digital output current value and a digital output voltage value of each digital electronic component 20. The digital output current values and the digital output voltage values of the plurality of digital electronic components 20 are stored in a first buffer 311 of the inter-integrated circuit 31.

The analog to digital converter 32 is connected to the plurality of analog electronic components 10 to test an analog output current value and an analog output voltage value of each analog electronic component 10. The analog to digital converter 32 converts the analog output current value and the analog output voltage value into digital information which is stored in a second buffer 321 of the analog to digital converter 32.

The main control module 33 is connected to the inter-integrated circuit 31 and the analog to digital converter 32. The main control module 33 can read out the information stored in the first buffer 311 and the second buffer 321. The UART module 34 is connected between the main control module 33 and the processor 50. The UART transmits data between the main control module 33 and the processor 50. The information stored in the first buffer 311 and the second buffer 321 can be transmitted to the processor 50 and processed by the processor 50.

The processor 50 processes the information stored in the first buffer 311 and the second buffer 321 to generate a monitoring result. The monitoring result is transmitted to the main control module 33. The main control module 33 controls the indicating unit 40 to indicate the monitoring result.

The indicating unit 40 includes a red light, a yellow light, and a green light. The main control module 33 lights the red light when a total power consumption of the plurality of digital electronic components 20 and the plurality of analog electronic components 10 is greater than a threshold value. The control module 33 lights the yellow light when the total power consumption is lower than the threshold value and greater than a normal value. The control module 33 lights the green light when the total power consumption is lower than the normal value.

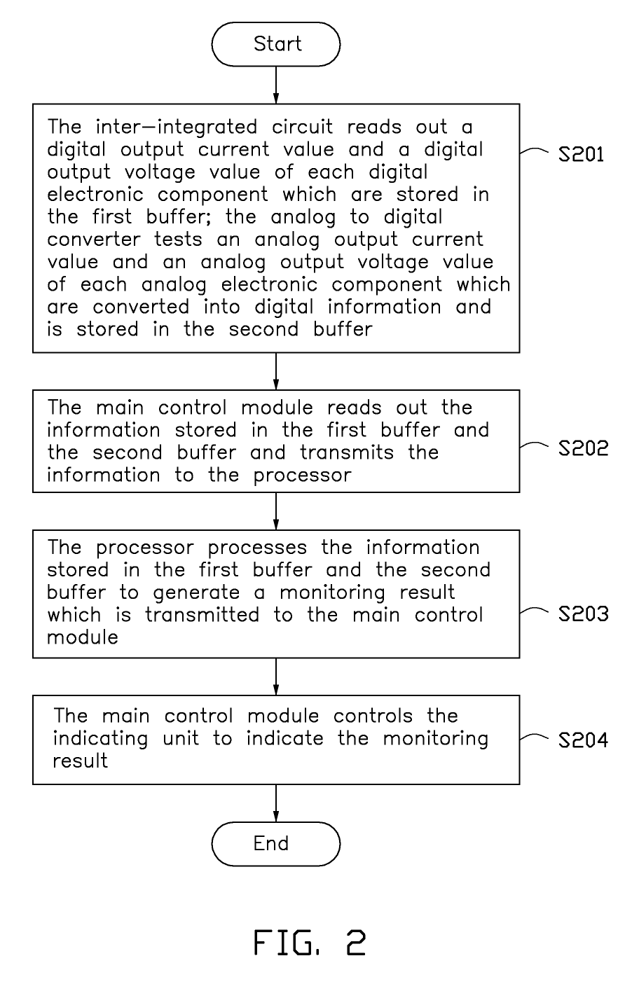

FIG. 2 is a flowchart showing one embodiment of a method for monitoring power consumption of the electronic device. The method comprises the following steps.

In step S201, the inter-integrated circuit 31 reads out a digital output current value and a digital output voltage value of each digital electronic component 20. The digital output current values and the digital output voltage values of the plurality of digital electronic components 20 are stored in the first buffer 311. The analog to digital converter 32 tests an analog output current value and an analog output voltage value of each analog electronic component 10, and the analog to digital converter 32 converts the analog output current value and the analog output voltage value into digital information which is stored in the second buffer 321.

In step S202, the main control module 33 reads out the information stored in the first buffer 311 and the second buffer 321, and the main control module 33 transmits the information to the processor 50.

In step S203, the processor 50 processes the information stored in the first buffer 311 and the second buffer 321 to generate a monitoring result. The monitoring result is transmitted to the main control module 33.

In step S204, the main control module 33 controls the indicating unit 40 to indicate the monitoring result.

Although numerous characteristics and advantages have been set forth in the foregoing description of embodiments, together with details of the structures and functions of the embodiments, the disclosure is illustrative only, and changes can be made in detail, especially in the matters of arrangement of parts within the principles of the disclosure to the full extent indicated by the broad general meaning of the terms in which the appended claims are expressed.

In particular, depending on the embodiment, certain steps or methods described may be removed, others may be added, and the sequence of steps may be altered. The description and the claims drawn for or in relation to a method may give some indication in reference to certain steps. However, any indication given is only to be viewed for identification purposes, and is not necessarily a suggestion as to an order for the steps.

What is claimed is:

1. A system for monitoring power consumption of an electronic device which comprises a plurality of analog electronic components and a plurality of digital electronic components, the system comprising:
a micro control unit comprising an inter-integrated circuit and an analog to digital converter, the inter-integrated circuit being connected to the plurality of digital electronic components and configured to record a digital output current value and a digital output voltage value of each of the plurality of digital electronic components, the analog to digital converter being configured to test an analog output current value and an analog output voltage value of each of the plurality of analog electronic components, and the analog to digital converter being configured to convert the analog output current value and the analog output voltage value into digital information;
a processor configured to process the digital output current value and the digital output voltage value of the inter-integrated circuit and the digital information of the analog to digital converter to generate a monitoring result; and
an indicating unit configured to indicate the monitoring result.

2. The system of claim 1, wherein the inter-integrated circuit comprises a first buffer, and the digital output current value and the digital output voltage value of each of the plurality of digital electronic components are stored in the first buffer.

3. The system of claim 1, wherein the analog to digital converter comprises a second buffer, and the digital information is stored in the second buffer.

4. The system of claim 1, wherein the indicating unit comprises a red light, a yellow light, and a green light.

5. The system of claim 4, wherein when a total power consumption of the plurality of digital electronic components and the plurality of analog electronic components is greater than a threshold value, the control module lights the red light; when the total power consumption is lower than the threshold value and greater than a normal value, the control module lights the yellow light; and when the total power consumption is lower than the normal value, the control module lights the green light.

6. A method for monitoring power consumption of an electronic device which comprises a plurality of analog electronic components and a plurality of digital electronic components, an inter-integrated circuit connected to the plurality of digital electronic components, an analog to digital converter connected to the plurality of analog electronic components, a processor, a control module, and an indicating unit, the method comprising:
the inter-integrated circuit recording a digital output current value and a digital output voltage value of each of the plurality of digital electronic components;
the analog to digital converter testing an analog output current value and an analog digital output voltage value of each of the plurality of digital electronic components;
the analog to digital converter converting the analog output current value and the analog digital output voltage value into digital information;
the processor processing the digital output current value and the digital output voltage value of the inter-integrated circuit and the digital information of the analog to digital converter;
generating a monitoring result; and
the indicating unit indicating the monitoring result.

7. The method of claim 6, further comprising storing the digital output current value and the digital output voltage value of each of the plurality of digital electronic components in a buffer of the inter-integrated circuit.

8. The method of claim 6, further comprising storing the digital information in a buffer of the analog to digital converter.

9. The method of claim 6, wherein the indicating unit comprises a red light, a yellow light, and a green light; the method further comprises the control module lighting the red light when a total power consumption of the plurality of digital electronic components and the plurality of analog electronic components is greater than a threshold value, the control module lighting the yellow light when the total power consumption is lower than the threshold value and greater than a normal value, the control module lighting the green light when the total power consumption is lower than the normal value.
